(19) United States
(12) Patent Application Publication
(10) Pub. No.: US 2017/0271145 A1
(43) Pub. Date: Sep. 21, 2017

(54) METHOD AND AN APPARATUS FOR CLEANING SUBSTRATES

(71) Applicant: SUSS MicroTec Photomask Equipment GmbH & Co. KG, Sternenfels (DE)

(72) Inventors: Uwe Dietze, Corona, CA (US); Jyh-Wei Hsu, HsinChu (TW); Martin Samoya, Corona, CA (US); SherJang Singh, Clifton Park, NY (US); Hrishi Shende, Boise, ID (US); Zhenxing Han, Boise, ID (US)

(21) Appl. No.: 15/075,257

(22) Filed: Mar. 21, 2016

(51) Int. Cl. H01L 21/02; G03F 1/82; B08B 3/08; H01L 21/67; B08B 3/02; B08B 3/12

(52) U.S. Cl. CPC H01L 21/02041; B08B 3/024; B08B 3/12; B08B 3/08; H01L 21/67051; G03F 1/82

(57) ABSTRACT

A method for cleaning substrates in which at least one nozzle arrangement is provided opposite to an exposed surface of a substrate to be cleaned. The nozzle arrangement includes at least two separate nozzles each having a sonic transducer arranged to introduce sonic energy into a liquid media flowing through the respective nozzle towards the surface of the substrate that is to be cleaned in such way that the sonic energy is directed towards the substrate surface. The sonic transducers have different resonant frequencies of the type that at least their respective first and second order harmonics are all different. A liquid media is applied to a surface area of the substrate by flowing liquid media through the at least two separate nozzles of the nozzle arrangement. The nozzles are arranged and positioned with respect to the surface of the substrate such that the media streams of the nozzles at least partially intersect each other prior to reaching the surface of the substrate. Sonic energy is introduced into the liquid flowing through the respective nozzles via the respective transducers such that interference of the frequencies provided by the respective transducers occurs above the surface of the substrate.

### FIELD OF THE INVENTION

The present invention relates to a method and an apparatus for cleaning substrates and in particular to a nozzle arrangement for this purpose. In particular, the present invention relates to a method and apparatus for cleaning substrates in the semiconductor field using liquid media in conjunction with sonic energy, so called ultrasound, and in particular, megasound.

### BACKGROUND OF THE INVENTION

It is known to dean components using ultrasound in many different technological fields. Components to be cleaned are typically brought into contact with a liquid medium and are exposed to ultrasound or rnegasound for a certain period of time in order to detach particles from the substrate surface by means of physical forces generated as the acoustic energy interacts with the liquid media in specific ways which are further described below. Ultrasonic and megasonic cleaning are also recognized techniques in the semiconductor field for wafer and mask production and are typically employed in different configurations. The industry refers to a process employing an acoustic energy with a frequency between 400 kHz and 700 kHz as ultrasonic cleaning, white a process employing a frequency above 700 kHz is referred to as megasonic cleaning. In the following description, the term sonic is used interchangeably to describe both ultrasonic as well as megasonic frequency ranges.

Sonic cleaning technology has been applied in surface cleaning over multiple decades. Various approaches are utilized depending on specific application requirements. In general, sonic cleaning approaches are divided into bath and spray configurations, respectively, each having specific advantages and disadvantages, but in general are substantially different approaches. In bath approaches, the substrate or a batch of substrates is typically fully immersed into a tank filled with specific cleaning media, usually liquid media. Sonic energy, introduced into the liquid media, enhances the cleaning capability of the liquid within the bath, wherein the sonic energy is typically not directed to a specific surface area to be cleaned, but generally into the liquid. In spray approaches, the cleaning media is dispensed from a nozzle or array of nozzles onto the substrate to be cleaned and typically will form a film of such media on the substrate surface. Sonic energy is introduced either into this film or into the stream of media which is dispensed onto the substrate and such sonic energy is specifically directed at the surface to be cleaned.

DE-A-197 58 267 A for example describes a bath system, in which a batch of semiconductor wafers is inserted into a treatment basin filled with liquid and then exposed to ultrasound. Hereby, the ultrasonic sound waves are directed substantially parallel to the surface of the wafers to achieve a substantially uniform cleaning effect over the surface of the wafer.

DE 10 2004 053 337 A for example describes a spray approach, where first a liquid film is formed on the surface of the substrate via a nozzle arranged adjacent to a sonic transducer and subsequently, sonic energy is coupled into the thus formed liquid film, and directed towards the substrate surface that is to be cleaned.

In bath and spray approaches, the use of multiple transducers of either same or different frequencies and/or acoustic power has been proposed with the goal of maximizing particle removal efficiency. In addition, frequency sweeping and on/of pulsing of sonic energy has been proposed to reduce the risk of unwanted surface or pattern damage.

Sonic technology utilizes piezoelectric transducers to deliver acoustic energy, which is coupled to the substrate surface(s) that are to be cleaned by means of liquid media. The acoustic energy transferred from the transducer into the media generates alternating cycles of low and high pressure in the medium, which in turn result in short pulses of bi-directional fluid motion on the substrate's surface. In the following description, we will address this fluid motion as primary acoustic streaming.

During low pressure cycles, the cleaning media may also form micro-bubbles, which can either be filled with gas that was contained in the media and is coming out of solution to fill these bobbles or by vapor of the media itself. During high pressure cycles, these bubbles are compressed and may either disappear at the rate of pressure increase or can also collapse violently (implode). Cycles of bubble formation and non-violent bubble compression are called stable cavitation. Cycles of bubble formation and violent bobble implosion are called transient cavitation.

In the case of stable cavitation, bubbles are usually re-forming at the same position where they were compressed, as gas and vapor concentrations accumulate locally here with each cycle, and as the bubbles grow further in size, stable cavitation may transition into transient cavitation. Both forms of cavitation produce additional fluid motion, which we shall call secondary acoustic streaming in this document.

Transient cavitation, due to its violent behavior results in more powerful secondary acoustic streaming, and therefore may be useful for fast (aggressive) particle removal (cleaning). However, such powerful secondary acoustic streaming can also result in unintended damage to the substrate's surface (so called pitting), or can lead to collapse of patterns built on the substrate's surface (so called pattern damage).

In comparison, stable cavitation results in much lower secondary acoustic streaming intensity, which reduces (less aggressive) the particle removal rata, but also mitigates the risk of surface pitting and pattern damage.

Although the above affects are well understood, no viable approach in controlling, in particular suppressing transient cavitation to reduce damage to the substrate surface or patterns, while keeping particle removal efficiency high has been found.

### SUMMARY OF THE INVENTION

It is a first object to provide sonic cleaning for substrates at reduced risk of damage to the substrate.

In accordance with one aspect, a method for cleaning substrates comprises providing at least one nozzle arrangement opposite to an exposed surface of a substrate to be cleaned, the nozzle arrangement comprising at least two separate nozzles each having a sonic transducer arranged to introduce sonic energy into a liquid media flowing through the respective nozzle towards the surface of the substrate that is to be cleaned in such way that said sonic energy is directed towards the substrate surface, wherein the sonic transducers have different resonant frequencies, of the type that at least their respective first and second order harmonics are all different. In the method liquid media is applied to a surface area of the substrate by flowing liquid media through the at least two separate nozzles of the nozzle arrangement, each nozzle creating a media stream, wherein the nozzles are arranged and positioned with respect to the surface of the substrate, such that the media streams of the at least two separate nozzles at least partially intersect each other prior to reaching the surface of the substrate and sonic energy is introduced into the liquid flowing through the respective nozzles via the respective transducers such that interference of the frequencies provided by the respective transducers occurs above the surface of the substrate. Such interference in the specific setup may lead to good primary acoustic streaming to provide energy for the cleaning process while reduced secondary acoustic streaming may occur compared to using a single frequency only.

In accordance with another aspect the at least two nozzles are arranged in-line to each other and tilted towards each other, and the distance between the nozzle arrangement and the surface of the substrate is adjusted to set the point of intersection between the media streams above the surface of the substrate. Adjusting the distance between the nozzle arrangement and the surface of the substrate, may be done such that the respective media streams intersect each other at a distance of between 5 to 25 mm from the surface of the substrate, wherein the at least two nozzles may be tilted towards each other at an angle between 15° to 45° with respect to a normal of the surface of the substrate.

According to another aspect the nozzle arrangement comprises at least three separate nozzles each having a sonic transducer associated therewith, such that the sonic transducers are arranged to introduce sonic energy into liquid media flowing through the respective nozzle towards the surface of the substrate that is to be cleaned in such way that said sonic energy is directed towards the substrate surface, wherein the sonic transducers have different resonant frequencies of the type that at least their respective first and second order harmonics are all different. In such a nozzle arrangement the sonic transducers may be arranged in a triangular manner such that the nozzles are tilted towards the middle of the triangular arrangement at an angle between 15° to 45° with respect to a normal of the surface of the substrate. However, other arrangements are possible.

In accordance with a further aspect, the resonant frequencies of the sonic transducers are at least 100 KHz apart and the sonic transducers may have a resonance frequency of at least about 3 MHz. In a specific aspect, one sonic transducer has a resonant frequency of about 3 MHz and another sonic transducer has a resonant frequency of about 5 MHz. In the three transducer example, a first sonic transducer may have a resonant frequency of about 3 MHz, a second sonic transducer may have a resonant frequency of about 4 MHz and a third sonic transducer may have a resonant frequency of about 5 MHz.

In accordance with a further aspect, the substrate is one of the following; a mask, in particular a photomask for the manufacture of semiconductors, a semiconductor material, in particular a Si-wafer, Ge-wafer, GaAs-wafer or an InP-wafer, a flat panel substrate, or a multi-layer ceramic substrate. The liquid media may employ at least one of the following; degasified DI water, DI water containing at least one dissolved gas, such including but not limited to CO₂, O₂, N₂, O₃, Ar and H₂, degasified or gasified DI water containing chemicals typically used for cleaning of substrate surfaces including but not limited to Surfactants, NH₄OH, acetic acid, citric acid, TMAH, ETMAH, TBAH, HNO₃, HCl, H₂O₂, H₃PO₄, BHF, EKC, ESC or compatible mixtures thereof.

in one aspect, the at least one of the nozzle arrangement and the substrate are moved with respect to the other to scan the liquid media over the substrate surface.

In accordance with another aspect, an apparatus for cleaning substrates is provided, comprising a receptacle for receiving a substrate to be cleaned such that a surface of substrate to be cleaned is exposed, and a nozzle arrangement comprising at least two separate nozzles each having a sonic transducer arranged to introduce sonic energy into a liquid media flowing through the respective nozzle in a nozzle outlet direction, wherein the sonic transducers have different resonant frequencies of the type that at least their respective first and second order harmonics are all different, wherein the nozzles are tilted towards a common point, such that respective media streams exiting the nozzles may at least partially intersect. The apparatus has a source of liquid media configured to simultaneously supply liquid to the separate nozzles of the nozzle arrangement, wherein the nozzles are arranged such that media streams exiting the respective nozzles may at least partially intersect prior to reaching the surface of the substrate, and a controller for controlling the operation of the respective sonic transducers, such that sonic energy is simultaneously introduced into the liquid media flowing through the respective nozzles. A positioning device positions the nozzle arrangement with respect to a substrate on the receptacle such that respective media streams flowing through and exiting the respective nozzles would at least partially intersect prior to reaching the substrate and causes relative movement between the nozzle arrangement and the substrate on the receptacle to scan the nozzle arrangement over the substrate surface.

According to another aspect, the at least two nozzles are arranged in-line to each other and tilted towards each other, and the positioning device may be configured to adjust the position of the nozzle arrangement with respect to the surface of the substrate on the receptacle, such that the respective media streams flowing through and exiting the respective nozzles intersect each other at a distance of between 5 to 25 mm from the surface of the substrate. The at least two nozzles may be tilted towards each other at an angle between 15° to 45° with respect to a normal of the surface of the substrate.

in a further aspect, the nozzle arrangement has at least three separate nozzles each having an outlet and a sonic transducer associated with each nozzle, such that the transducers are arranged to introduce sonic energy into a liquid media flowing through the respective nozzle in a nozzle outlet direction, wherein the sonic transducers have different resonant frequencies of the type that at least their respective first and second order harmonics are all different, in such a three nozzle arrangement the nozzles may be arranged in a triangular manner such that the nozzles are tilted towards the middle of the triangular arrangement at an angle between 15° to 45° with respect to a normal of the surface of the substrate.

In accordance with a further aspect the resonant frequencies of the sonic transducers are at least 100 KHz apart. The sonic transducers may have a resonant frequency of at least about 3 MHz. According to a specific aspect one sonic transducer may have a resonant frequency of about 3 MHz and another sonic transducer may have a resonant frequency of about 5 MHz. In the at least three nozzle arrangement, a first sonic transducers may have a resonant frequency of about 3 MHz, a second sonic transducer may have a resonant frequency of about 4 MHz and a third sonic transducer may have a resonant frequency of about 5 MHz.

### BRIEF DESCRIPTION OF THE DRAWINGS

The present invention is described in more detail hereinafter on the basis of an exemplary embodiment taken with reference to the drawings; in the drawings:

FIG. 1 shows a schematic top view of a cleaning apparatus according to the present invention;

FIG. 2a and 2b show schematic sectional views of a nozzle arrangement of FIG. 1 in different positions;

FIG. 3 shows a schematic sectional view of another nozzle arrangement in accordance with the present invention;

FIG. 4 shows a schematic bottom view of a triangular arrangement of nozzles of the nozzle arrangement of FIG. 3.

### DETAILED DESCRIPTION

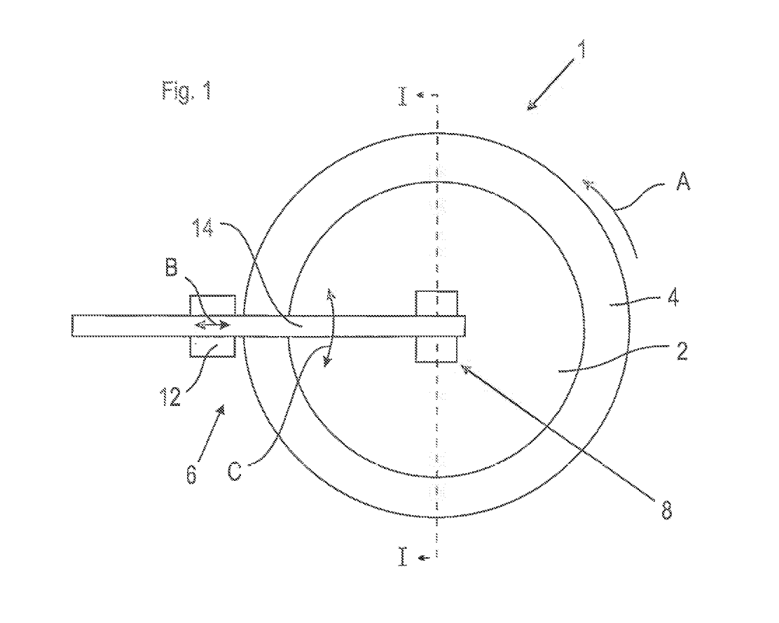

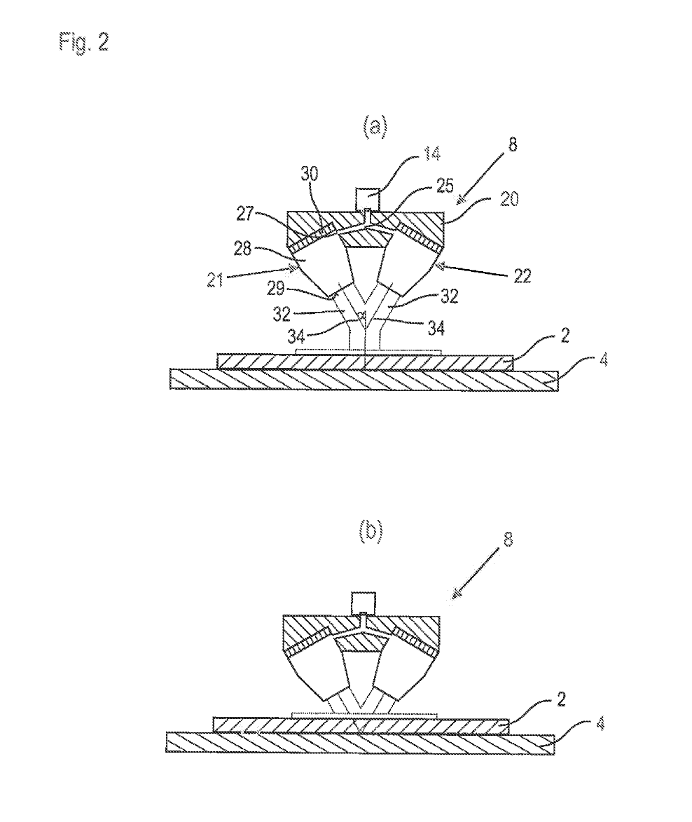

FIG. 1 shows a schematic top view of a cleaning apparatus 1 for cleaning substrates 2, while FIG. 2 shows a schematic sectional view of a nozzle arrangement of the apparatus 1 along the line I-I. The cleaning apparatus 1 basically consists of a receptacle for the substrate, which will be called a substrate holder 4 and an application unit 6.

The substrate holder 4 is, as may be seen in the drawings, a flat circular plate for receiving the substrate 2, which in the embodiment as shown also has a circular shape. The substrate holder 4 may have other shapes such as rectangular, which may be matched to the shape of the substrate 2 to be treated, it is also possible that substrate holder 4 and substrate 2 have different shapes. The substrate holder 4 has a drainage, which is not shown, for liquids, which may be applied via the application unit 6 onto the substrate 2. As indicated by the arrow A, the substrata holder 4 is configured to be rotated by means of a respective rotation device (not shown).

The application unit 6 consists of a nozzle arrangement 8 and a carrying structure 10, which supports the nozzle arrangement 8 in a movable manner. The carrying structure 10 has a main part 12 adjacent the substrate bolder 4 and a support arm 14 supported by the main part 12 in a longitudinally movable manner as is shown by the double-headed arrow B. The support arm 14 supports the nozzle arrangement 8 on its free end. By moving the support arm 14, the nozzle arrangement 8 may be scanned across the substrate 2. Such scanning movement of the nozzle arrangement 8 in combination with a rotation of the substrate 2 via the substrate bolder 4 allows the nozzle arrangement 8 to be scanned over the complete surface of the substrate 2. Rather than providing a linear movement of the support arm 14 as shown, also a swinging motion of the same may be provided as indicated by the double headed arrow C. Furthermore, a lift structure for the support arm 14 is provided on the main part 12, to enable a lifting movement in order to adjust a distance between the nozzle arrangement 8 and the surface of a substrate 2 received on the substrate holder 4. The skilled person will easily recognize other arrangements for scanning the nozzle arrangement 8 over the substrate 2 and for providing a distance adjustment between nozzle arrangement 8 and substrate 2. As it would be clear to the skilled person, it would also be possible to provide a stationary substrate holder 4 or to move the substrate holder 4 and the nozzle arrangement 8 in a different manner, to achieve a relative movement between the substrate 2 and the nozzle arrangement 8 to allow the scanning of the nozzle arrangement 8 over the substrate surface. The main part 12 of the carrying structure includes a source of liquid or is connected therewith, which is connected in a suitable manner with nozzles of the nozzle arrangement 8, which will be described in more detail herein below. The main part 12 may also house a controller to control the movement of one of the substrate holder and the nozzle arrangement the application of liquid media to the nozzle arrangement and/or electrical equipment for driving sonic transducers, as will be explained in more detail herein below. Such a controller may also be provided as a separate controller housed outside the main part 12.

FIG. 2a and 2b show schematic sectional views of the nozzle arrangement 8 according to a first embodiment (along line I-I of FIG. 1) positioned at different distances above a substrate 2 to be treated. The nozzle arrangement 8 has a main body 20 and two nozzles 21, 22 attached to or integrally formed with the main body 20. The main body 20 may be made of any suitable material for supporting or forming the nozzles 21 and 22 and is attached in a suitable manner to the support arm 14.

The main body 20 has an internal conduit 25 connecting a top of the main body 20 and flow chambers formed in the respective nozzles. The conduit 25 is a branched conduit, providing a common branch which is connected at the top of the main body 20 with a common supply line (not shown) provided in or on the support arm 14. The conduit 25 also has two nozzle branches, connecting the common branch with one of the nozzles 21, 22 each.

The nozzles 21, 22, which are only schematically shown each have in substance the same basic structure and thus only nozzle 21 will be described herein with respect to the common features. Nozzle 21 has an inlet 27 connected to the conduit 25, a flow chamber 28 and an outlet 29. Nozzle 21 also has a sonic transducer 30 arranged to introduce sonic energy into the flow chamber. The inlet 27 opens into the flow chamber 28 at a position adjacent the sonic transducer 30 and distanced from the outlet 29. The conduit 25, the inlet 27, the flow chamber 28 and the outlet 29 are dimensioned, such that liquid media supplied via supply line may fully fill the flow chamber 28 and may form a directed jet or stream of liquid media as indicated at 32 in FIG. 2. Nozzle 21 is angled with respect to a surface of the substrate holder 4 (or a substrate 2 thereon) such that the directed stream 32 exiting the outlet 29 forms an angle a of between 15° to 45°, preferably about 30° with respect to a normal of the surface of the substrate (as schematically indicated in FIG. 2a).

The sonic transducer 30 is arranged to form an end of the flow chamber 23 which is opposite the outlet 29 and to introduce sonic energy into the flow chamber 28 in a direction in substance parallel to the directed stream 32 exiting the outlet 29.

As indicated above, nozzles 21, 22 have the same basic structure. The sonic transducers 30 associated with the respective nozzles 21, 22, however, are not identical and at least differ with respect to their resonant frequencies. Not only are the resonant frequencies different, but the different resonant frequencies are such that at least their respective first and second order harmonics are all different (i.e. neither the resonant frequencies nor any of the first and second order harmonics have the same value). Both sonic transducers preferably have a resonant frequency above 3 MHz even one or both may also have a lower resonant frequency. In particular a combination of a 3 MHz transducer in one nozzle and a 5 MHz transducer in the other nozzle has been found beneficial in the above two nozzle design. However other combinations are also possible. The resonant frequencies of the sonic transducers 30 have to be at least 100 KHz, preferable 200 KHz apart. As such, both sonic transducers may for example be so called 5 MHz transducers, which deviate from a resonant frequency of 5 MHz, within a normal range of up to 100 KHz. As such, a so called 5 MHz transducer having a real resonant frequency of 4.9 MHz may be used in combination with another so called 5 MHz transducer having a real resonant frequency offer example 5.1 MHz, thus creating a real difference between the resonant frequencies of 200 KHz. Any combination of sonic transducers 30 having (real) resonant frequencies which are at least 100 KHz apart and fulfill the requirements with respect to the harmonics not being the same may provide benefits, even though larger separations of the resonant frequencies are currently preferred. Although 3 and 5 MHz are given as example frequencies, the skilled person will realize that other frequencies may be used, also non-integer frequencies such as 3.5 Mhz.

Furthermore, nozzle 22 is angled differently, i.e. not parallel to the nozzle 21. Nozzles 22 is also angled with respect to a surface of the substrate holder 4 (or a substrate 2 thereon) such that a directed stream exiting its outlet forms an angle of between 15° to 45° preferably about 30° with respect to a normal of the surface of the substrate. The nozzles 21, 22 are angled towards a common point such that the respective directed streams intersect each other, if they are not intercepted. In particular, the nozzles 21, 22 may be arranged in line and tilted towards each other in a symmetrical manner (plane symmetry).

The streams are considered to fully intersect, if their respective centers, as indicated by center lines 34, may intersect without being intercepted by an object, as shown in FIG. 2a. The streams are considered to partially intersect, if the respective streams contact each other but their respective centers may not intersect as they are intercepted by an object, as for example shown in FIG. 2b. The position closest to the respective nozzles where the respective streams contact each other will be called point of intersect in the following. In either case, the respective streams exiting the nozzles 21, 22 will form a common media film on the substrate 2.

As indicated above, FIGS. 2a and 2b show the nozzle arrangement 8 positioned at different distances above a substrate 2 to be treated. As may be seen by these Figures, adjusting the distance between the nozzle arrangement 8 and the substrate 2 changes the distance between the point of intersect and the surface of the substrate. Such an adjustment may be made via a suitable lifting movement of at least one of the support arm 14 and the substrate holder 4.

Although a common supply line connected to a common branch of integrated conduit is shown, it is noted that separate conduits one for each nozzle 21, 22 may be provided, integrally in the main body 20 or external thereto and that such separate conduits could either be connected to a common supply line or to separate supply lines, which would allow application of different media via the respective nozzles as would be clear to the skilled person.

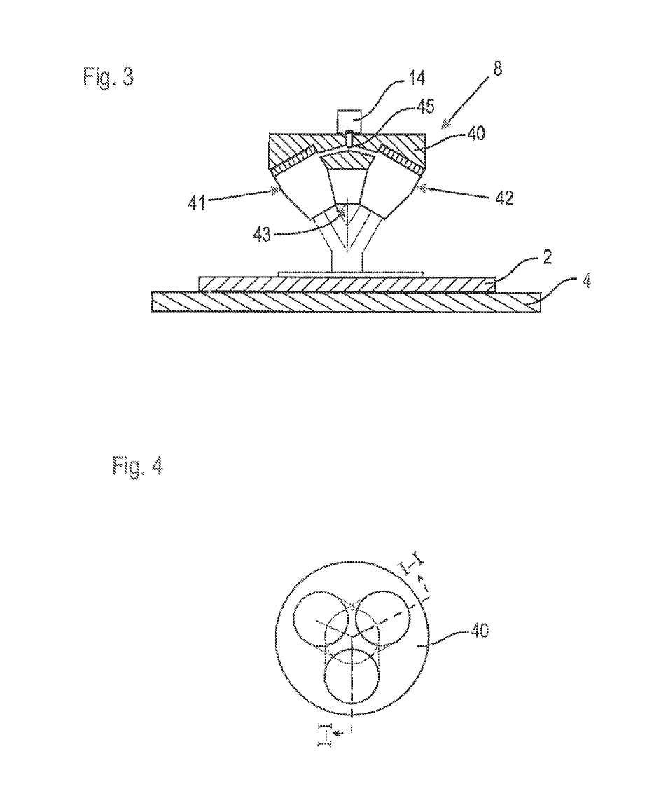

FIGS. 3 and 4 show an alternative nozzle arrangement 8, wherein FIG. 3 shows a schematic sectional view of the nozzle arrangement along line II-II in FIG. 4, which shows a simplified schematic bottom view thereof.

The alternative nozzle arrangement has a main body 40 and three nozzles 41, 42 and 43. The main body 40 has an internal conduit 45 connecting a top of the main body 40 and flow chambers formed in the respective nozzles 41, 42 and 43 similar to the structure of main body 20 described above, but having respective branches for each of the three nozzles. The conduit 45 is connected at the top of the main body 40 with a common supply line (not shown) provided in or on the support arm 14. Again, the conduit may be different and not an integrated one.

Each of the nozzles 41, 42 and 43 has the same basic structure as nozzle 21 described above, having an inlet, a flow chamber, an outlet and a sonic transducer associated therewith. Each transducer is again capable of producing a directed media stream. The respective transducers again ail differ with respect to their resonant frequencies. The different resonant frequencies are again such that at least their respective first and second order harmonics are ail different (i.e. neither the resonant frequencies nor any of the first and second order harmonics have the same value). Preferably, all transducers have a resonant frequency above 3 MHz even one or more may also have a lower resonant frequency. In particular a combination of a 3 MHz transducer in s first nozzle, a 4 MHz transducer in a second nozzle and a 5 MHz transducer in a third nozzle are presently considered to be beneficial in the above three nozzle design. However, again other combinations are possible, wherein the difference between the resonant frequencies of any two of the sonic transducers 30 has to be at least 100 KHz, preferable 200 KHz.

Furthermore, nozzles 41, 42 and 43 are arranged in a triangular pattern as seen from below, with each of the nozzles 41, 42 and 43 being angled, such that a directed stream exiting its outlet forms an angle of between 15° to 45°, preferably about 30° with respect to a line normal to the surface of the substrate. The nozzles 41, 42 and 43 are angled towards a common area or point such that the respective directed streams all intersect each other, if they are net intercepted. In particular, the nozzles 41, 42 and 43 may be tilted towards the middle of the triangular arrangement.

The streams are again considered to fully intersect, if all of their respective centers may intersect without being intercepted by an object, as shown in FIG. 3. The streams are considered to partially intersect, if all the respective streams contact each other but their respective centers may not intersect as they are intercepted by an object. The position closest to the respective nozzles where the respective streams contact each other will be called point of intersect in the following. In either case, the respective streams exiting the nozzles 41, 42 and 43 will form a common media film on the substrate 2.

In the following, a cleaning operation using the above cleaning apparatus 1 will be described. For describing the operation, it is assumed that the nozzle arrangement 8 is of the two nozzle design and nozzles 21, 22 are considered to have 3 MHz and 5 Mhz sonic transducers, respectively. A Substrate 2 such as a structured semiconductor wafer (other substrates are possible as will be indicated herein below) is present on the substrata holder 4, which is of the rotating type and rotates.

The nozzle arrangement 8 is positioned above the center of the wafer, which coincides with the center of rotation of the substrate holder 4. Liquid media typically used for cleaning of semiconductor wafers including for example DI water and HCl (other liquid media are possible as will be indicated herein below) is supplied to the nozzles 21, 22 of the nozzle arrangement 8 such that each nozzle 21, 22 forms a directed jet or stream 32 of the liquid media. The nozzle arrangement 8 is positioned above the substrate 2 such that the media streams fully intersect each other above the surface of the substrate 2 as for example shown in FIG. 2a. The sonic transducers 30 are driven at their respective resonance frequency and thus introduce sonic energy into the respective directed streams 32 which intersect each other above the substrate surface and thereby forming an intermixed combined stream directed onto the substrate to form a common liquid film on the substrate. The nozzle arrangement is then moved (linearly of in a swinging motion) towards and over an edge of the rotating substrate thereby scanning the liquid film over the complete substrate surface, cleaning the same, wherein the cleaning is enhanced by acoustic streaming within the liquid media. In particular, good cleaning is achieved in the area of the combined stream being applied to the surface of the substrate.

As indicated above, the respective streams 32, into each of which sonic energy of a frequency different to the frequency of the other stream is introduced via the respective transducer 30, fully intersect above the surface of the substrate 2. This allows the different frequencies to interfere above the surface of the substrate and even in an area of the respective streams before they intersect. The inventors have found that such interference of different frequencies (especially of frequencies above 3 MHz) leads to a reduction or even a complete suppression of transient cavitation, i.e. violent bubble implosions, compared to the application of a single media stream into which a single frequency is introduced. This leads to more controlled (more homogeneous) secondary acoustic streaming in the liquid media, while not substantially influencing primary acoustic streaming. The specific application of the different media streams which intersect each other above the surface and into which the different frequencies are introduced thus enables good particle removal efficiency while reducing the risk of damages to the substrate.

Even though in the above example, the respective streams are fully intersecting, the interference effect will also occur if the streams only partially intersect. Nevertheless at present full intersection of the streams is preferred. In either case, it is deemed beneficial if the point of intersect of the streams is controlled to be at a position of 5 to 25 mm above the surface of the substrate to be cleaned during the cleaning operation.

While the 3 MHz, 5 Mhz resonant frequency combination for the transducers has been found to be particularly beneficial, other combinations are also considered to lead to a respective reduction in of transient cavitation, as long as the resonant frequencies are at least 100 KHz apart and at least the first and second harmonics of the respective frequencies are all different. Preferably all frequencies used should be above 3 MHz as the sizes of bubbles formed during low pressure cycles are reduced with higher frequencies, thereby further reducing the risk of transient cavitation occurring.

Similar effects may be achieved when using the three nozzle design of the nozzle arrangement 8 in the above manner. Also higher numbers of nozzles can be used even though such higher numbers lead to a more complicated structure of the nozzle arrangement.

The above cleaning operation is deemed to be particularly beneficial for any substrate having a surface or a structure thereon which is prone to damage by transient cavitation occurring during sonic enhanced cleaning of the same. Non-limiting examples of such substrates are a mask, in particular a photomask for the manufacture of semiconductors, having for example sob-resolution assist features, a semiconductor material, in particular a semiconductor wafer having for example fins or metal lines, such as a Si-wafer, a Ge-wafer, a GaAs-wafer or an InP-wafer, a flat panel substrate, or a multi-layer ceramic substrate. Different liquid media may be employed in such a cleaning operation, which media may be specifically selected for the substrate to be cleaned. The liquid media employed preferably uses at least one of the following: degasified DI water, DI water containing at least one dissolved gas, such including but not limited to CO₂, O₂, N₂, O₃, Ar and H₂, degasified or gasified DI water containing chemicals typically used for cleaning of substrate surfaces including but not limited to Surfactants, NH₄OH, acetic acid, citric acid, TMAH, ETMAH, TBAH, HNO₃, HCl, H₂O₂, H₃PO₄, BHF, EKC, ESC or compatible mixtures thereof, wherein compatible mixtures are ail mixtures which do not lead to undesired reactions between the constituents of the mixture. Although two and three nozzles have been shown in the specific examples, it should be noted that a higher number of nozzles can also be used.

The invention has been described with reference to specific embodiments thereof without being limited to the specific embodiments. From the above description those skilled in the art will perceive improvements, changes and modifications. Such improvements, changes and modifications within the skill of the art are intended to be covered by the appended claims.

1. A method for cleaning substrates, comprising:
providing at least one nozzle arrangement opposite to en exposed surface of a substrate to be cleaned, the nozzle arrangement comprising at least two separate nozzles each having a sonic transducer arranged to introduce sonic energy into a liquid media flowing through the respective nozzle towards the surface of the substrate that is to be cleaned in such way that said sonic energy is directed towards the substrate surface, wherein the sonic transducers have different resonant frequencies, of the type that at least their respective first and second order harmonics are all different;
applying liquid media to a surface area of the substrate by flowing liquid media through the at least two separate nozzles of the nozzle arrangement, each nozzle creating a media stream, wherein the nozzles are arranged and positioned with respect to the surface of the substrate, such that the media streams of the at least two separate nozzles at least partially intersect each ether prior to reaching the surface of the substrate; and
introducing sonic energy into the liquid flowing through the respective nozzles via the respective transducers such that interference of the frequencies provided by the respective transducers occurs above the surface of the substrate.

2. The method of claim 1, wherein the at least two nozzles are arranged in-line to each other and tilted towards each other, the method further comprising:
adjusting the distance between the nozzle arrangement and the surface of the substrate, to adjust the point of intersection between the media streams above the surface of the substrate.

3. The method of claim 2, further comprising adjusting the distance between the nozzle arrangement and the surface of the substrate, such that the respective media streams intersect each other at a distance of between 5 to 25 mm from the surface of the substrate.

4. The method of claim 2, wherein the at least two nozzles are tilted towards each other at an angle between 15° to 45° with respect to a normal of the surface of the substrate.

5. The method of claim 1, wherein the nozzle arrangement comprises at least three separate nozzles each having a sonic transducer associated therewith, such that the sonic transducers are arranged to introduce sonic energy into liquid media flowing through the respective nozzle towards the surface of the substrate that is to be cleaned in such way that said sonic energy is directed towards the substrate surface, wherein the sonic transducers have different resonant frequencies of the type that at least their respective first and second order harmonics are all different.

6. The method of claim 5, wherein the sonic transducers are arranged in a triangular manner such the nozzles are tilted towards the middle of the triangular arrangement at an angle between 15° to 45° with respect to a normal of the surface of the substrate.

7. The method of claim 1, wherein the resonant frequencies of the sonic transducers are at least 100 KHz apart.

8. The method of claim 1, wherein the sonic transducers have a resonance resonant frequency of at least about 3 MHz.

9. The method of claim 1, wherein one sonic transducer has a resonant frequency of about 3 MHz and another sonic transducer has a resonant frequency of about 5 MHz.

10. The method of claim 5, wherein a first sonic transducer has a resonant frequency of about 3 MHz, a second sonic transducer has a resonant frequency of about 4 MHz and a third sonic transducer has a resonant frequency of about 5 MHz.

11. The method of claim 1, wherein the substrate to be cleaned is one of the following: a mask, in particular a photomask for the manufacture of semiconductors, a semiconductor material, in particular a Si-wafer, Ge-wafer, GaAs-wafer or an InP-wafer, a flat panel substrate, or a multi-layer ceramic substrate.

12. The method of claim 1, wherein the liquid media employs at least one of the following is used: degasified DI water, DI water containing at least one dissolved gas, such including but not limited to CO₂, O₂, N₂, O₃, Ar and H₂, degasified or gasified DI water containing chemicals typically used for cleaning of substrate surfaces including but not limited to Surfactants, NH₄OH, acetic acid, citric acid, TMAH, ETMAH, TBAH, HNO₃, HCl, H₂O₂, H₃PO₄, BHF, EKC, ESC or compatible mixtures thereof.

13. The method of claim 1, wherein at least one of the nozzle arrangement and the substrate are moved with respect to the other to scan the liquid media over the substrate surface.

14. An apparatus for cleaning substrates comprising:
a receptacle for receiving a substrate to be cleaned such that a surface of substrate to be cleaned is exposed;
a nozzle arrangement comprising at least two separate nozzles each having a sonic transducer arranged to introduce sonic energy into a liquid media flowing through the respective nozzle in a nozzle outlet direction, wherein the sonic transducers have different resonant frequencies of the typo that at least their respective first and second order harmonics are ail different, wherein the nozzles are tilted towards a common point such that respective media streams exiting the nozzles may at least partially intersect;
a source of liquid media, the source being configured to simultaneously supply liquid to the separate nozzles of the nozzle arrangement, wherein the nozzles are arranged such that media streams exiting the respective nozzles may at least partially intersect prior to reaching the surface of the substrate;
a controller for controlling the operation of the respective sonic transducers, such that sonic energy is simultaneously introduced info the liquid media flowing through the respective nozzles; and
a positioning device, for positioning the nozzle arrangement with respect to a substrate on the receptacle such that respective media streams flowing through and exiting the respective nozzles would at least partially intersect prior to reaching the substrate and for causing relative movement between the nozzle arrangement and the substrata on the receptacle to scan the nozzle arrangement over the substrate surface.

15. The apparatus of claim 14, wherein the at least two nozzles are arranged in-line to each other and tilted towards each other.

16. The apparatus of claim 15, wherein the positioning device is configured to adjust the position of the nozzle arrangement with respect to the surface of the substrate on the receptacle, such that the respective media streams flowing through and exiting the respective nozzles intersect each other at a distance of between 5 to 25 mm from the surface of the substrate.

17. The apparatus of claim 15, wherein the at least two nozzles are tilted towards each other at an angle between 15° to 45° with respect to a normal of the surface of the substrate.

18. The apparatus of claim 15, wherein the nozzle arrangement comprises at least three separate nozzles each having an outlet and a sonic transducer associated with each nozzle, such that the transducers are arranged to introduce sonic energy into a liquid media flowing through the respective nozzle in a nozzle outlet direction, wherein the sonic transducers have different resonant frequencies of the type that at least their respective first and second order harmonics are all different.

19. The apparatus of claim 18, wherein the sonic transducers are arranged in a triangular manner such that the nozzles are tilted towards the middle of the triangular arrangement at an angle between 15° to 45° with respect to a normal of the surface of the substrate.

20. The apparatus of claim 15, wherein the resonant frequencies of the sonic transducers are at least 100 KHz apart.

21. The apparatus of claim 15, wherein the sonic transducers have a resonant frequency of at least about 3 MHz.

22. The apparatus of claim 15, wherein one sonic transducer has a resonant frequency of about 3 MHz and another sonic transducer has a resonant frequency of about 5 MHz.

23. The method of claim 18, wherein a first sonic transducers has a resonant frequency of about 3 MHz, a second sonic transducer has a resonant frequency of about 4 MHz and a third sonic transducer has a resonant frequency of about 5 MHz.
